(19) United States
(12) Patent Application Publication
(10) Pub. No.: US 2009/0325387 A1
(43) Pub. Date: Dec. 31, 2009

(54) METHODS AND APPARATUS FOR IN-SITU CHAMBER DRY CLEAN DURING PHOTOMASK PLASMA ETCHING

(75) Inventors: Xiaoyi Chen, Foster City, CA (US); Zhigang Mao, San Jose, CA (US); David Knick, Sunnyvale, CA (US); Michael Grimbergen, Redwood City, CA (US); Darin Bivens, San Mateo, CA (US); Madhavi Chandrahood, Sunnyvale, CA (US); Ibrahim Ibrahim, Santa Clara, CA (US); Ajay Kumar, Cupertino, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/147,341

(22) Filed: Jun. 26, 2008

(51) Int. Cl. H01L 21/3065; B44C 1/22

(52) U.S. Cl. 438/710; 216/67; 216/60; 257/E21.218

(57) ABSTRACT

Embodiments of the invention include method for in-situ chamber dry clean after photomask plasma etching. In one embodiment, the method includes placing a photomask upon a support pedestal, introducing a process gas into a process chamber, forming a plasma from the process gas, etching a chromium containing layer disposed on the photomask in the presence of the plasma, removing the photomask from the support pedestal, placing a dummy substrate on the pedestal and performing an in-situ dry cleaning process by flowing a cleaning gas containing O₂ through the process chamber while the dummy substrate is disposed on the support pedestal.

### BACKGROUND

1. Field

Embodiments of the present invention generally relate to method and apparatus for processing a photomask substrate using plasma etching. Particularly, embodiments of the present invention relate to methods and apparatus for in-situ chamber dry clean during plasma etching of photomask substrates.

2. Description of the Related Art

The fabrication of microelectronics or integrated circuit devices typically involves a complicated process sequence requiring hundreds of individual steps performed on semiconductive, dielectric and conductive substrates. Examples of these process steps include oxidation, diffusion, ion implantation, thin film deposition, cleaning, etching and lithography. Using lithography and etching (often referred to as pattern transfer steps), a desired pattern is first transferred to a photosensitive material layer, e.g., a photoresist, and then to the underlying material layer during subsequent etching. In the lithographic step, a blanket photoresist layer is exposed to a radiation source through a reticle or photomask, which is typically formed in a metal-containing layer supported on a glass or quartz substrate, containing a pattern so that an image of the pattern is formed in the photoresist. By developing the photoresist in a suitable chemical solution, portions of the photoresist are removed, thus resulting in a patterned photoresist layer. With this photoresist pattern acting as a mask, the underlying material layer is exposed to a reactive environment, e.g., using dry etching, which results in the pattern being transferred to the underlying material layer.

An example of a commercially available photomask etch equipment suitable for use in advanced device fabrication is the TETRA® Photomask Etch System, available from Applied Materials, Inc., of Santa Clara, Calif. The metal-containing layers patterned by a plasma processing such as photomask plasma etching process offers better critical dimension control than conventional wet chemical etching in the fabrication of microelectronic devices. Plasma etching technology is widely applied in the semiconductor and thin film transistor-liquid crystal display (TFT-LCD) industry.

During dry etching photomasks in the plasma chamber, materials such as chromium (Cr), MoSi, quartz, SiON or Ta-based compounds may be deposited and forming layers of film stacks. One example of a film stack may comprise layers of photoresist, Cr and quartz. After etching has been performed, etching by-products may be accumulated and deposited on the inner wall of the chamber. The by-products may be determined using Optical Emission Spectra (OES) during etching process. For example, when dry etching Cr, the etch by-products found by OES are predominantly photoresist with some Cr. When the deposited etch by-products reach a certain thickness, the by-products may peel off the inner wall and contaminate the photomask by falling onto the substrate, causing irreparable defects to the photomask. Accordingly, it is important to remove such deposited etching by-products.

One conventional method for cleaning the plasma chamber is to open the chamber and then disassemble the components therein. Thereafter, the etching by-products are removed by a physical or chemical method. For example, deionized water (DIW) and isopropanol (IPA) is used to clean the components and inner wall of the chamber. However, such a wet cleaning approach is time-consuming, resulting in the disadvantage of reduced mask production. In-situ dry cleaning has also been utilized in other plasma chambers, but commercially viable in-situ dry cleaning processes suitable for photomask etch processes are not known.

Therefore, there is a need for an improved process for chamber cleaning suitable for photomask fabrication.

### SUMMARY

Embodiments of the invention include methods for in-situ chamber dry clean after photomask plasma etching. In one embodiment, a method is provided and includes placing a substrate such as a photomask upon a support pedestal, introducing a process gas into a process chamber, forming a plasma from the process gas, etching a chromium containing layer disposed on the photomask in the presence of the plasma, removing the etched photomask from the support pedestal, placing a dummy substrate on the support pedestal, and performing an in-situ dry cleaning process by flowing a cleaning gas containing O2 through the process chamber while the dummy substrate is on the support pedestal.

In other embodiment, a method for in-situ chamber dry clean during photomask plasma etching includes placing a photomask upon a support pedestal disposed in a process chamber, plasma etching a chromium containing layer disposed on the photomask while applying bias power, removing the etch photomask from the process chamber, and performing an in-situ dry cleaning process without bias power in the presence of a cleaning plasma formed from a cleaning gas containing O2 after the etched photomask has been removed from the process chamber.

In one embodiment, a method for in-situ chamber dry clean includes using a chlorine-free cleaning plasma. In other embodiment, a method for in-situ chamber dry clean includes using a chlorine and oxygen containing cleaning plasma. In yet another embodiment, a method for in-situ chamber dry clean includes cleaning plasma in the absence of bias power.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of a processing chamber for photomask plasma etching according to one embodiment of the invention;

FIG. 2 is a flow chart of a method for cleaning a plasma chamber after photomask plasma etching according to one embodiment of the invention; and

FIG. 3 is a graph showing a steady state condition comparison between oxygen (O₂) and chlorine (Cl₂) when used as cleaning gas according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention provide methods and apparatus for in-situ chamber dry clean during photomask plasma etching.

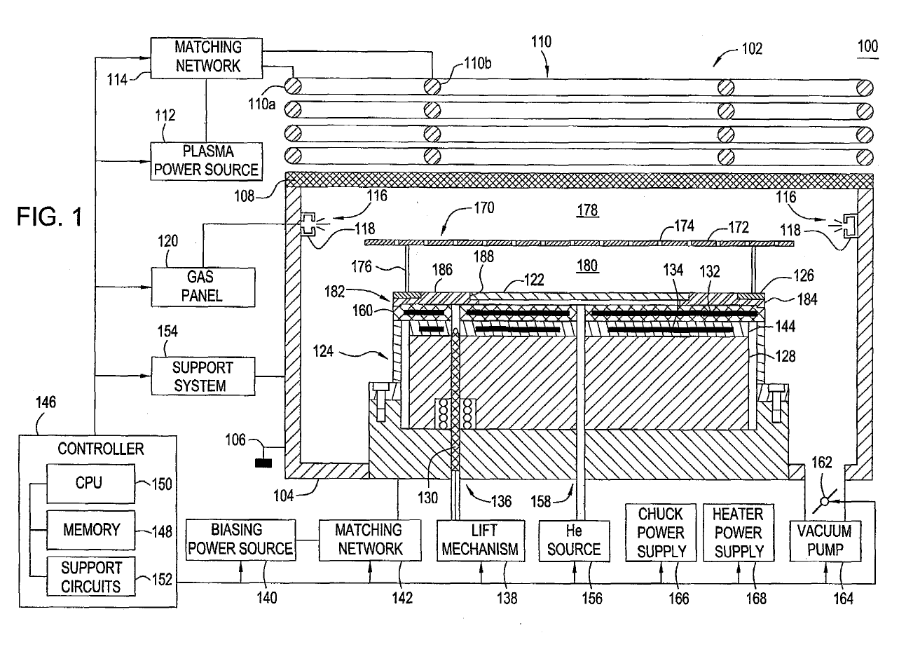

FIG. 1 depicts a schematic diagram of an etch reactor 100 in which the invention may be practiced. Suitable reactors that may be adapted for use with the teachings disclosed herein include, for example, a Decoupled Plasma Source (DPS® II) reactor, or a TETRA® Photomask etch system, all of which are available from Applied Materials, Inc. of Santa Clara, Calif. The particular embodiment of the reactor 100 shown herein is provided for illustrative purposes and should not be used to limit the scope of the invention. It is contemplated that the invention may be utilized in other plasma processing chambers, including those from other manufacturers.

The reactor 100 generally comprises a process chamber 102 having a substrate pedestal 124 within a conductive body (wall) 104, and a controller 146. The process chamber 102 has a substantially flat dielectric ceiling or lid 108. Other modifications of the process chamber 102 may have other types of ceilings, e.g., a dome-shaped ceiling. An antenna 110 is disposed above the ceiling 108 and comprises one or more inductive coil elements that may be selectively controlled (two co-axial elements 110a and 110b are shown in FIG. 1). The antenna 110 is coupled through a first matching network 114 to a plasma power source 112, which is typically capable of producing up to about 3000 W at a tunable frequency in a range from about 50 kHz to about 13.56 MHz.

The substrate pedestal (cathode) 124 is coupled through a second matching network 142 to a biasing power source 140. The biasing source 140 generally is a source of up to about 500 W at a frequency of approximately 13.56 MHz that is capable of producing either continuous or pulsed power. Alternatively, the source 140 may be a DC or pulsed DC source.

In one embodiment, the substrate support pedestal 124 comprises an electrostatic chuck 160, which has at least one clamping electrode 132 and is controlled by a chuck power supply 166. In alternative embodiments, the substrate pedestal 124 may comprise substrate retention mechanisms such as a susceptor cover ring, a mechanical chuck, and the like.

A reticle adapter 182 is used to secure the substrate (e.g., mask or reticle) 122 onto the substrate support pedestal 124. The reticle adapter 182 generally includes a lower portion 184 that covers an upper surface of the pedestal 124 (for example, the electrostatic chuck 160) and a top portion 186 having an opening 188 that is sized and shaped to hold the substrate 122. The opening 188 is generally substantially centered with respect to the pedestal 124. The adapter 182 is generally formed from a single piece of etch resistant, high temperature resistant material such as polyimide ceramic or quartz. An edge ring 126 may cover and/or secure the adapter 182 to the pedestal 124.

A lift mechanism 138 is used to lower or raise the adapter 182, and hence, the substrate 122, onto or off of the substrate support pedestal 124. Generally, the lift mechanism 162 comprises a plurality of lift pins 130 (one lift pin is shown) that travel through respective guide holes 136.

In operation, the temperature of the substrate 122 is controlled by stabilizing the temperature of the substrate pedestal 124. In one embodiment, the substrate support pedestal 124 comprises a resistive heater 144 and a heat sink 128. The resistive heater 144 generally comprises at least one heating element 134 and is regulated by a heater power supply 168. A backside gas, e.g., helium (He), from a gas source 156 is provided via a gas conduit 158 to channels that are formed in the pedestal surface under the substrate 122 to facilitate heat transfer between the pedestal 124 and the substrate 122. During processing, the pedestal 124 may be heated by the resistive heater 144 to a steady-state temperature, which in combination with the backside gas, facilitates uniform heating of the substrate 122. Using such thermal control, the substrate 122 may be maintained at a temperature between about 0 and 350 degrees Celsius (° C.).

An ion-radical shield 170 may be disposed in the process chamber 102 above the pedestal 124. The ion-radical shield 170 is electrically isolated from the chamber walls 104 and the pedestal 124 such that no ground path from the plate to ground is provided. One embodiment of the ion-radical shield 170 comprises a substantially flat plate 172 and a plurality of legs 176 supporting the plate 172. The plate 172, which may be made of a variety of materials compatible with process needs, comprises one or more openings (apertures) 174 that define a desired open area in the plate 172. This open area controls the amount of ions that pass from a plasma formed in an upper process volume 178 of the process chamber 102 to a lower process volume 180 located between the ion-radical shield 170 and the substrate 122. The greater the open area, the more ions can pass through the ion-radical shield 170. As such, the size of the apertures 174 controls the ion density in volume 180, and the shield 170 serves as an ion filter. The plate 172 may also comprise a screen or a mesh wherein the open area of the screen or mesh corresponds to the desired open area provided by apertures 174. Alternatively, a combination of a plate and screen or mesh may also be used.

During processing, a potential develops on the surface of the plate 172 as a result of electron bombardment from the plasma. The potential attracts ions from the plasma, effectively filtering them from the plasma, while allowing neutral species, e.g., radicals, to pass through the apertures 174 of the plate 172. Thus, by reducing the amount of ions through the ion-radical shield 170, etching of the mask by neutral species or radicals can proceed in a more controlled manner. This reduces erosion of the resist as well as sputtering of the resist onto the sidewalls of the patterned material layer, thus resulting in improved etch bias and critical dimension uniformity.

Prior to plasma etching, one or more process gases are provided to the process chamber 102 from a gas panel 120, e.g., through one or more inlets 116 (e.g., openings, injectors, nozzles, and the like) located above the substrate pedestal 124. In the embodiment of FIG. 1, the process gases are provided to the inlets 116 using an annular gas channel 118, which may be formed in the wall 104 or in gas rings (as shown) that are coupled to the wall 104. During the etch process, a plasma formed from the process gases is maintained by applying power from the plasma source 112 to the antenna 110.

The pressure in the process chamber 102 is controlled using a throttle valve 162 and a vacuum pump 164. The temperature of the wall 104 may be controlled using liquid-containing conduits (not shown) that run through the wall 104. Typically, the chamber wall 104 is formed from a metal (e.g., aluminum, stainless steel, among others) and is coupled to an electrical ground 106. The process chamber 102 also comprises conventional systems for process control, internal diagnostic, end point detection, and the like. Such systems are collectively shown as support systems 154. In one embodiment, Optical Emission Spectra (OES) may be used as an end point detection tool.

The controller 146 comprises a central processing unit (CPU) 150, a memory 148, and support circuits 152 for the CPU 150 and facilitates control of the components of the process chamber 102 and, as such, of the etch process, as discussed below in further detail. The controller 146 may be one of any form of general-purpose computer processor that can be used in an industrial setting for controlling various chambers and sub-processors. The memory, or computer-readable medium, 642 of the CPU 150 may be one or more of readily available memory such as random access memory (RAM), read only memory (ROM), floppy disk, hard disk, or any other form of digital storage, local or remote. The support circuits 152 are coupled to the CPU 150 for supporting the processor in a conventional manner. These circuits include cache, power supplies, clock circuits, input/output circuitry and subsystems, and the like. The inventive method is generally stored in the memory 148 as a software routine. Alternatively, such software routine may also be stored and/or executed by a second CPU (not shown) that is remotely located from the hardware being controlled by the CPU 150.

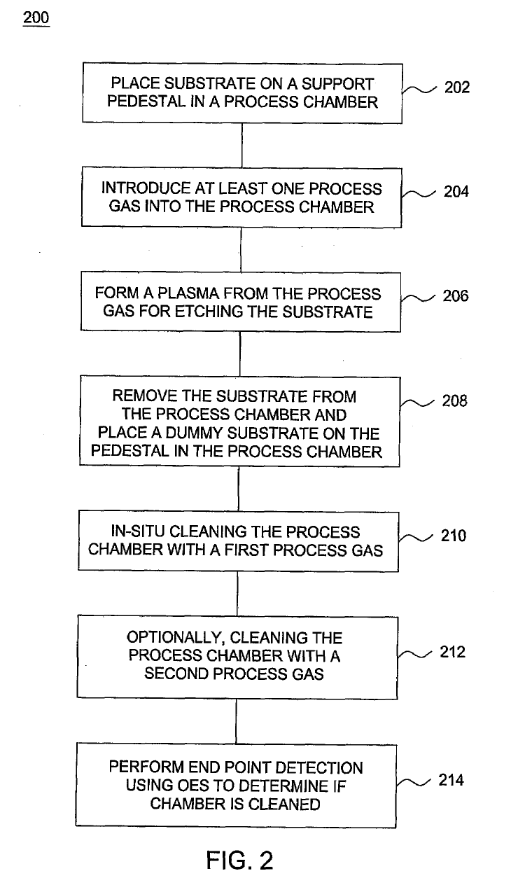

FIG. 2 illustrates a method 200 for etching a photomask that includes an in-situ chamber dry clean according to embodiments of the present invention. The method 200 begins at block 202 when the substrate is placed on a support pedestal in a process chamber. In embodiments wherein an ion shield is present, the shield may comprise two zones having at least one characteristic, e.g., material or potential bias, being different from each other. The substrate to be etched may include an optically transparent silicon based material, such as quartz (i.e., silicon dioxide, SiO₂), having an opaque light-shielding layer of metal disposed on the surface of the quartz. Opaque light-shielding metals generally comprise a chromium-containing material, such as chromium or chromium oxynitride. The substrate may also include a layer of silicon nitride (SiN) doped with molybdenum (Mo) interposed between the quartz and chromium.

At block 204, one or more process gases are introduced into the process chamber through a gas inlet. Exemplary process gases may include oxygen (O₂) or an oxygen-containing gas, such as carbon monoxide (CO), and/or a halogen-containing gas, such as a chlorine-containing gas for etching the metal layer. The processing gas may further include an inert gas or another oxygen-containing gas. Carbon monoxide is advantageously used to form passivating polymer deposits on the surfaces, particularly the sidewalls, of openings and patterns formed in a patterned resist material and etched metal layers. Chlorine-containing gases are selected from the group of chlorine (Cl₂), silicon tetrachloride (SiCl₄), hydrochloride (HCl), and combinations thereof, and are used to supply reactive radicals to etch the metal layer.

Optionally, a DC bias voltage may be applied to at least one zone of the ion-radical shield. At block 206, a plasma is formed from the one or more process gases in a process volume above the ion-radical shield, for example, by applying RF power between about 200 to about 2000 W from a plasma power source to an antenna. Ions and neutral species from the plasma pass through the ion-radical shield according to a distribution pattern determined by the potentials established by the applied bias voltage and the plasma across the ion-radical shield. The substrate is etched by the ions and neutral species in the lower process volume.

At block 208, substrate is removed from the support pedestal inside the process chamber and a dummy substrate is placed on the pedestal with the pedestal protected by the dummy substrate, an in-situ dry cleaning is performed.

In one embodiment, the in-situ dry cleaning includes introducing a cleaning gas containing O₂ (e.g., a first cleaning gas) into the process chamber via the gas inlet at block 210. A plasma is formed from the cleaning gas to clean the chamber. Optionally, at block 212, a second cleaning gas may be introduced into the process chamber via the gas inlet and energized to a plasma state with the first cleaning gas. While dry cleaning is being performed inside the process chamber, end point detection of the dry clean process is performed using OES to determine if the by-product in the process chamber has been removed at block 214. In one embodiment, a pre-determined time can also be used to determine the removal of the by-product. After the cleaning process is complete, the process chamber is now ready for the next etching process.

In one embodiment, the dry cleaning can be performed using oxygen (O₂) as a first cleaning gas with a flow rate between 50 to 1000 standard cubic centimeters per minute (sccm), for example, from about 50 to 400 sccm, such as at about 100 sccm. Oxygen can be used to remove etching by-products that remain after photomask etching. Accordingly, RF power can be applied from a plasma power source in a range between 150 and 1500 W, for example, from about 300 to 1000 W, for example, about 600 W to an antenna. The pressure in the process chamber can be controlled between about 2 to 50 mTorr, for example, from about 3 to 20 mTorr, for example, about 8 mTorr. The power ratio of the outer/inner coils (CPR) can be controlled between 15 to 85%, for example, from about 15 to 75%, for example, about 55%. The process chamber may be exposed to the process gas for a time period of about 200 seconds.

In one embodiment, the cleaning gas is chlorine-free. In another embodiment, the cleaning plasma is formed from the cleaning gas in the absence of bias power.

In another embodiment, the dry cleaning can also be performed using second cleaning along with the first cleaning gas. The first cleaning gas may be supplied as indicated above. Chlorine (Cl₂) may be supplied as the second cleaning gas at a flow rate between 25 to 500 sccm, for example, from about 50 to 400 sccm, for example, at about 100 sccm. Accordingly, RF power can be applied from a plasma power source in a range between 150 and 1500 W, for example, from about 300 to 1000 W, and more preferably, about 600 W to an antenna. The pressure in the process chamber can be controlled between about 2 to 50 mTorr, preferably, from about 3 to 20 mTorr, for example, about 8 mTorr. The power ratio of the outer/inner coils (CPR) can be controlled between 15 to 85%, preferably, from about 15 to 75%, and more preferably, about 55%. The process chamber may be exposed to the process gas for a time period of about 200 seconds. In another embodiment, the cleaning plasma containing both oxygen and chlorine is formed from the cleaning gas in the absence of bias power

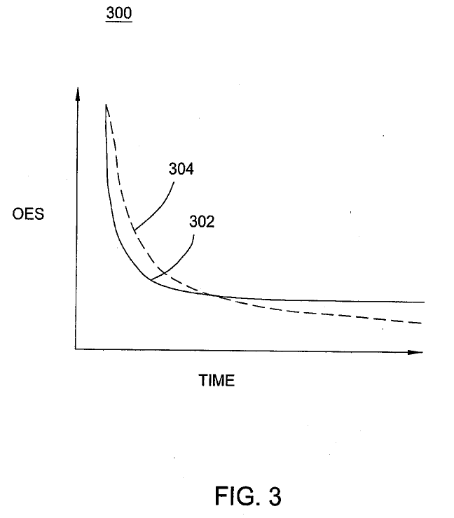

FIG. 3 is a graph 300 showing a steady state condition comparison between O₂ and Cl₂ when used as cleaning gas according to one embodiment of the present invention. The steady state condition may be measured using OES while determining the removal of the by-product over time. The steady state condition is shown in two lines, one line 302 represents the state condition for O₂ and one line 304 represents the state condition for Cl₂. When using Cl₂ as the process gas during the dry cleaning process, although Cl₂ may be used to remove the by-products inside the process chamber, however, due to the aggressive nature of the Cl₂, after the removal of the by-products, Cl₂ may also continue to attack the process chamber surface, particularly the surface of the plate 172 which is layered with quartz and has a plurality of apertures 174 to control the distribution of ions in the process chamber. This is shown in line 304 as the slope for the line 304 representing Cl₂ continue to decline after the initial dry cleaning step. Thus, during the cleaning process, the condition of the process chamber never reached a steady state condition needed for repeatable processing. In contrary, when using O₂ as the process gas, the slope for the line 302 represent O₂ reaches closer to a flat line, closer to steady state, which is more suitable for repeatable processing. Therefore the use of the O₂ gas is needed to help the removal of Cl₂ and return the state condition to a steady state so that the process chamber may be used for repeatable processing of substrates.

While the foregoing is directed to embodiments of the present invention, other and further embodiments of the invention may be devised without departing from the basic scope thereof, and the scope thereof is determined by the claims that follow.

1. A method for in-situ chamber dry clean after photomask plasma etching, comprising:
placing a photomask upon a support pedestal;
introducing a process gas into a process chamber;
forming a plasma from the process gas;
etching a chromium containing layer disposed on the photomask in the presence of the plasma;
removing the photomask from the support pedestal; and
performing an in-situ dry cleaning process by flowing a cleaning gas containing O₂ through the process chamber while the dummy substrate is disposed on the support pedestal.

2. The method of claim 1 further comprising:
using an end point detection device to determine if by-products of the etch are sufficiently removed from the chamber.

3. The method of claim 1, wherein the cleaning gas does not contain chlorine.

4. The method of claim 1, wherein the cleaning gas further comprises chlorine.

5. The method of claim 3, wherein the cleaning gas comprises oxygen provide at a rate of about 50 to about 1000 sccm.

6. The method of claim 2, wherein the end point detection device monitors optical emission spectra.

7. The method of claim 1, wherein a flow rate of oxygen in the cleaning gas is between about 50 to about 1000 sccm, and wherein a flow rate of chlorine in the cleaning gas about 25 to about 500 sccm.

8. The method of claim 1, wherein a flow rate of oxygen in the cleaning gas is between about 50 to about 400 sccm, and wherein a flow rate of chlorine in the cleaning gas about 50 to about 400 sccm.

9. The method of claim 1, wherein a flow rate of oxygen in the cleaning gas is between about 100 sccm, and wherein a flow rate of chlorine in the first cleaning gas about 100 sccm.

10. The method of claim 1, wherein the dry clean process is performed in the absence of bias power.

11. The method of claim 1, wherein the process chamber has an internal pressure during the dry cleaning process of about 2 to 50 mTorr.

12. The method of claim 1, wherein the RF power is utilized to maintain a plasma formed from the cleaning gas, the RF power applied a range between 150 and 1500 W in absence of bias power.

13. The method of claim 12, wherein the RF power is applied to outer and inner coils positioned adjacent the chamber at a power ratio of outer to inner coils of between about 15 to about 85 percent.

14. A method for in-situ chamber dry clean after photomask plasma etching, comprising:
placing a photomask upon a support pedestal disposed in a process chamber;
plasma etching a chromium containing layer disposed on the photomask while applying bias power;
removing the etched photomask from the process chamber; and
performing an in-situ dry cleaning process without bias power in the presence of a cleaning plasma formed from a cleaning gas containing O₂ after the etched photomask has been removed from the process chamber.

15. The method of claim 14, wherein performing the in-situ dry cleaning process further comprises:
providing Cl₂ in the cleaning gas.

16. The method of claim 15, wherein a flow rate of oxygen in the cleaning gas is between about 50 to about 1000 sccm, and wherein a flow rate of chlorine in the cleaning gas about 25 to about 500 sccm.

17. The method of claim 15, wherein a flow rate of oxygen in the cleaning gas is between about 50 to about 400 sccm, and wherein a flow rate of chlorine in the cleaning gas about 50 to about 400 sccm.

18. The method of claim 16, wherein the RF power is utilized to maintain the cleaning plasma, the RF power applied a range between 150 and 1500 W in absence of bias power.

19. The method of claim 16, wherein the RF power is applied to outer and inner coils positioned adjacent the chamber at a power ratio of outer to inner coils of between about 15 to about 85 percent.

20. The method of claim 14 further comprising:
placing a dummy substrate on the pedestal after the etched photomask has been removed; and
performing the in-situ dry clean while the dummy substrate is disposed on the support pedestal.
